(19) United States
(12) Patent Application Publication
(10) Pub. No.: US 2010/0321679 A1
(43) Pub. Date: Dec. 23, 2010

(54) MEASUREMENT SYSTEM AND METHOD

(76) Inventors: Boaz Brill, Rehovoth (IL); Shimon Sandik, Petach-Tikva (IL)

Correspondence Address: DANIEL J SWIRSKY, 55 REUVEN ST., BEIT SHEMESH, 99544, IL

(21) Appl. No.: 12/808,366

(22) PCT Filed: Dec. 16, 2008
(86) PCT No.: PCT/IL2008/001627

§ 371 Date: Sep. 1, 2010

(30) Foreign Application Priority Data
Dec. 16, 2007 (IL) 188155

(51) Int. Cl. G01N 21/88

(52) U.S. Cl. 356/237.5

(57) ABSTRACT

A multi-station measurement system concept is presented, particularly based on an X-Y stage and plurality of horizontal load/unload units. The system allows loading/unloading of wafers from several load/unload units by the direct action of the X-Y stage, thus creating a buffer for wafers without actually requiring an additional buffer mechanism.

### FIELD OF THE INVENTION

The present invention relates generally to substrate processing systems and techniques, such as those used in semiconductor manufacturing and in particular to optical based processing such as metrology or inspection of semiconductor wafers.

### BACKGROUND

It is known in the art cluster measurement system including a measurement units and a wafer handling unit (Equipment Front-End Module “EFEM”) transferring wafers between measuring system(s) and wafer containers (FOUP's). Such a tool is known from U.S. Pat. No. 7,030,401 in the Name of Nanophotonics AG. Transfer means is arranged to transfer wafers between the containers and the measurement units through the handling unit.

In order to reduce cycle time overhead, several separate metrology units are linked by an automation platform that handles wafer transport between the metrology units and a substrate container interface. Although the cluster tool is designed to provide increased throughput, the system is quite complex and expensive.

### SUMMARY OF THE INVENTION

It is the objective of the present invention to provide a solution for these problems by low cost and high reliability simple system configuration and operational sequence. In accordance with one general aspect of the invention is to provide a system of moderate cost and method of wafer handling for high throughput metrology tool.

Generally, a multi-station measurement system concept is presented, particularly based on an X-Y stage and plurality of horizontal load/unload units. The system allows loading/unloading of wafers from several load/unload units by the direct action of the X-Y stage, thus creating a buffer for wafers without actually requiring an additional buffer mechanism. Such system configuration is thus capable of increasing throughput over standard system configurations, at a lower cost and higher reliability (lower number of moving parts), better utilizing throughput capacity of Wafer Transfer Robot. The system also supports measurements using a number of measuring channels without the need to reload or realign the wafer, thus, sharing wafer-handling resources (e.g. when one of the channels is infrequently used) and/or saving time (if several different measurements are required for the same wafer). Accordingly, this system potentially presents a lower cost-of-ownership for the end user in a large number of cases.

### BRIEF DESCRIPTION OF DRAWINGS

The present invention will be understood and appreciated more fully from the following detailed description taken in conjunction with the appended drawings in which:

FIG. 1 is a schematic top view diagram showing a substrate measurement system according to a first embodiment,

FIG. 2 is a schematic top view diagram showing a substrate measurement system according to second embodiment, and

FIG. 3 presents timing charts of different system components.

### DETAILED DESCRIPTION

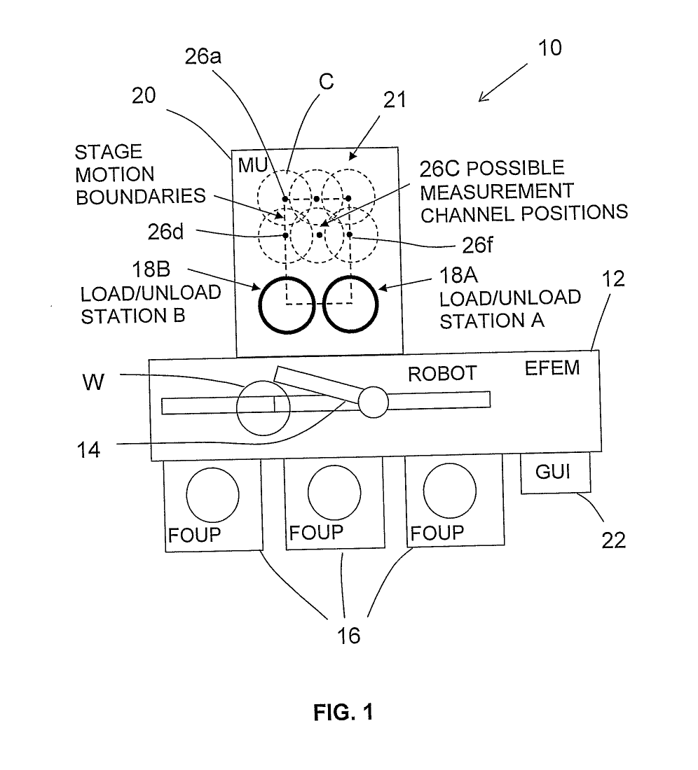

FIG. 1 shows a substrate (a wafer W in the present embodiment) measurement system 10 comprising a wafer handling unit (EFEM) 12 provided with a wafer transfer means (single or multiple robot) 14 having one or more end-effectors (not shown). Term “measurement” also means inspection in the present invention. A unit 12 as a part of Equipment Front-End Module (“EFEM”) provides interface to the FAB and includes load ports for wafer cassettes (FOUP's) 16. Wafer transfer means 14 provides wafers transferring from the cassettes 16 to load/unload units 18a and/or 18b of a measurement unit (MU) 20 preferably provided by a X-Y stage 21. System 10 could be provided with graphical user interface (GUI) 22 and additional optional features such as aligner and ID reader (not shown).

Plurality of load/unload units 18a and 18b (two in the present example) are substantially separated in horizontal plane and designed for receiving/unloading wafers from/to end-effectors of robot 14. Also, load/unload units 18a, 18b provides wafers transferring onto/from stage 21 of MU 20. Optionally, each or one of load/unload units 18a 18b could include additional means 24 providing additional functionalities such as notch finding and ID reading, etc. The vertical transfer of wafers between load/unload units 18a 18b and X-Y stage 21 could be done either by using loading/unloading units with wafer handling assembly having Z-axis movement actuator or by providing X-Y stage with additional movable Z-axis (not shown).

Examples of appropriate wafer handling assembly and stage could found in U.S. Pat. No. 6,964,276 in the name of Nova Measuring Instruments Ltd incorporated herein by reference. X-Y stages used in the field are equipped with a mechanism for holding/transferring wafers that has sufficient travel range to enable pick and transfer wafers from/to different locations, in the present invention plurality loading units. Common used vacuum, edge gripping or other type chuck could be used for wafer holding. X-Y stage 21 generally provides moving wafer W in horizontal plane for bringing each point on the wafer (within a pre-define area on the wafer, e.g. excluding edge exclusion zone) to one or more measuring position(s) 26a-26f enabling measurement using one or more of the measurement channels (not shown) accordingly. Optionally, X-Y stage 21 could be also equipped with a rotation (theta) mechanism, enabling rotation of the wafer by 90 or 180 degrees thereby reducing the range of the X-Y travel (e.g. about radius of wafer W) and footprint accordingly. Rotation is required in order to enable scanning the entire or desired surface area of wafer W.

One or more measurement channels 26a-26f (six in the present example) could provide either measurement or inspection of at least part of the wafer based on Spectral Reflectometry, Ellipsometry, Spectral Ellipsometry, a laser-based optical system, VUV, X-ray, etc. Measurement channels with measuring position(s) 26a-26f could provide various thin film parameters including optical characteristics and other parameters, OCD, defect inspection, overlay measurement, measurement of crystal parameters. Additionally, measuring channels could provide vision and/or alignment, etc.

Circles C in dash lines in FIG. 1 show the extreme wafer positions provided by X-Y stage 21 while scanning wafer W. A rectangle R shows the range in which the center of X-Y stage 21 (generally corresponding to the center of wafer W) should travel in order to cover all required measurement positions, entire wafer surface in the present example.

In accordance with the present invention, configuration of system 10 provides a buffering for incoming and outgoing wafers W, potentially separating the operation of MU 20 from operation of wafer transfer robot 14 of the EFEM 16. Such separation allows optimization of the overall system throughput as will be demonstrated furtherbelow.

In accordance with one aspect of the present invention, as illustrated in FIG. 1 the system 10 includes an X-Y-Theta stage providing a travel range which is slightly larger than the wafer diameter in the X direction and slightly larger than 1.5 the wafer W diameters in the Y direction. This configuration allows at least six different potential measurement positions where scanning the whole wafer at the central two position is done by X-Y and 180 rotation while for scanning the full wafer at the outer four positions also 90 degree rotations are required (which are not suitable for some measurement channels, such as Ellipsometry). This system is also could be equipped with a dual-blade robot 14 and load/unload units 18a and/or 18b providing wafer W notch-finding functionality.

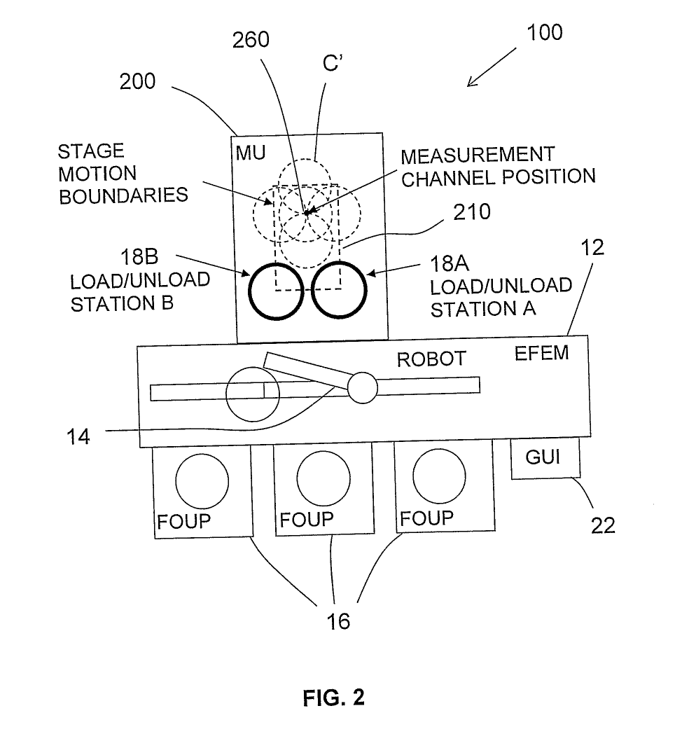

FIG. 2 illustrates yet another embodiment of the present invention. In this case a measurement system 100 includes X-Y stage 210 with increase range of Y-axis motion in order to provide “pure” X-Y scanning under the measurement position 260 without the need to use a rotation (theta) stage. Two configurations of FIG. 1 and FIG. 2 could be combined, creating a measurement system that supports one measurement position which is scanned by only X-Y motion and addition measurement positions which can be used with the help of some rotation motion (90 or 180 degrees). Circles C′ in dash lines show the extreme wafer positions provided by X-Y stage 210 while scanning wafer W.

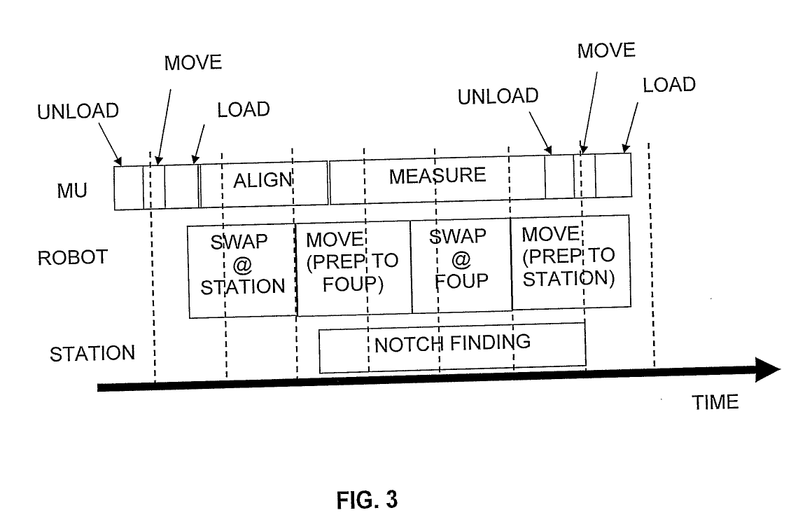

A typical time sequence that utilizes the capabilities systems 10 and 100 is illustrated in FIG. 3. The sequence includes the following steps:

1. Starting position: One wafer located on chuck of X-Y stage 21 (210) and measurement is performed. Second wafer is loaded on load/unload unit 18a, after optional Notch finding (alignment). Third wafer is held by one of the robot's 14 arms positioned next to load/unload unit 18b.

2. Measurement performed.

3. X-Y stage 21 (210) moves to load/unload unit 18b and unloads the measured wafer thereon.

4. X-Y stage 21 (210) moves to load/unload unit 18a and loads a wafer to be measured.

5. MU 20 (200) performs measurement and to alignment and measurement.

6. Robot 14 picks up measured wafer from load/unload unit 18b with empty arm.

7. Robot 14 loads unmeasured wafer from first arm on load/unload unit 18b.

8. MU 20 (210) starts notch finding on wafer located on load/unload unit 18b

9. Robot 14 moves to one of FOUP's 16 and swaps wafers.

10. Robot 14 moves back to waiting position next to load/unload unit 18a

11. End of cycle.

As seen in FIG. 3, since three different operations could be actually performed in parallel, the system 10 (100) is optimized for throughput while leaving sufficient time for each operation to be successfully completed. Eventually this sequence allows the measurement channel (the “effective” part of the system) to be the bottleneck, rather than the wafer handling operations (the “overhead”) to be dominant.

A limited number of embodiments have been described. Nevertheless, it will be understood that various modifications may be made without departing from the spirit and scope of the disclosure. Accordingly, other embodiments are within the scope of the following claims.

1. A measurement system comprising:
a substrate handling unit provided with a substrate transfer means,
at least one substrate cassette connected to said substrate handling unit,
a measurement unit connected to said substrate handling unit, said measurement unit comprising at least two load/unload units and a X-Y substrate supporting stage. cm 2. The measurement system comprising in accordance with claim 1, wherein said X-Y substrate supporting stage has a travel range about 1.5 of substrate diameter in one of axis.

3. The measurement system in accordance with claim 2, wherein said X-Y substrate supporting stage further comprising means for the substrate rotating.

4. The measurement system in accordance with claim 3, wherein said means for the substrate rotation provides rotational range from 0 up to 90 degrees.

5. The measurement system in accordance with claim 3, wherein said means for the substrate rotation provides rotational range from 0 up to 180 degrees.

6. The measurement system in accordance with claim 1, wherein said X-Y substrate supporting stage further comprising means for movement the substrate along vertical axis.

7. The measurement system in accordance with claim 1, wherein measurement unit said comprises at least two measurement channels.

8. The measurement system in accordance with claim 7, wherein said measurement channels includes at least one of a Spectral Reflectometer, an Ellipsometer, a Spectral Ellipsometer, a laser-based optical system, a VUV optical channel, X-ray.

9. The measurement system in accordance with claim 1, wherein said at least one load/unload units of said measurement unit further comprises Notch finding assembly.

10. The measurement system in accordance with claim 1, wherein said at least one load/unload unit further comprising means for movement the substrate along vertical axis.

11. The measurement system in accordance with claim 1, wherein said Substrate transfer means comprises a robot having at least one end-effectors.

12. The measurement system in accordance with claim 11, wherein said Substrate transfer means comprises a robot having at least two end-effectors.

13. The measurement system in accordance with claim 11, wherein said substrate is a semiconductor wafer.
